(19) United States
(12) Patent Application Publication
(10) Pub. No.: US 2011/0187414 A1
(43) Pub. Date: Aug. 4, 2011

(54) PBTI TOLERANT CIRCUIT DESIGN

(75) Inventor: Yen-Huei CHEN, Hsinchu (TW)

(73) Assignee: TAIWAN SEMICONDUCTOR MANUFACTURING COMPANY, LTD., Hsinchu (TW)

(21) Appl. No.: 12/697,431

(22) Filed: Feb. 1, 2010

(51) Int. Cl. G11C 7/00; H03K 3/356

(52) U.S. Cl. 327/57; 327/208

(57) ABSTRACT

In an embodiment related to a sense amplifier, the sense amplifier includes a cross latch includes a pair of nodes, a first pair of transistors, a second pair of transistors, a third node, and a circuit. The pair of nodes includes a first node and a second node configured to store data for the sense amplifier. The second pair of transistors includes a first NMOS transistor and a second NMOS transistor. A first gate of the first NMOS transistor is coupled to the first node, and a second gate of the second NMOS transistor is coupled to the second node. The third node is coupled to a first source of the first NMOS transistor and a second source of the second NMOS transistor. When appropriate, the circuit is configured to provide a voltage level to the third node.

### FIELD OF THE DISCLOSURE

The present disclosure is generally related to integrated circuit design. In various embodiments, a sense amplifier is Positive Bias Temperature Instability (PBTI) tolerant.

### BACKGROUND

Traditionally, oxide poly gates are commonly used in transistors with 40 nanometer (nm) and above semiconductor manufacturing processes. Positive Bias Temperature Instability (PBTI) effects for NMOS transistors in such situations are commonly ignored because the Negative Bias Temperature Instability (NPTI) for PMOS transistors are dominant and are generally of main concern. As semiconductor manufacturing technologies advance to 32 nm, 22 nm, etc., high K/metal gates are being used in place of oxide poly gates. High K refers to a dielectric material having a dielectric constant (K value) higher than that of silicon dioxide, which is about 3.9. As PBTI can affect circuit performance in a high K/metal gate, there is a need to address that problem.

### SUMMARY

In an embodiment related to an integrated circuit, the circuit includes a cross latch that in turns includes a pair of nodes, a first pair of transistors, a second pair of transistors, a third node, and a circuitry. The pair of nodes includes a first node and a second node configured to store data for the cross latch. The second pair of transistors includes a first NMOS transistor and a second NMOS transistor; a first gate of the first NMOS transistor being coupled to the first node; a second gate of the second NMOS transistor being coupled to the second node. Third node couples a first source of the first NMOS transistor and a second source of the second NMOS transistor. When appropriate, the circuitry is configured to provide a voltage level to the third node. Other embodiments including those related to sense amplifiers are also disclosed.

Embodiments of the present disclosure can have one or a combination of the following features and/or advantages. Embodiments mitigate the PBTI effect including that on sense amplifiers, and as a result, stabilize the sense amplifiers.

### BRIEF DESCRIPTION OF THE DRAWINGS

The details of one or more embodiments are set forth in the accompanying drawings and the description below. Other features and advantages of the invention will be apparent from the description, drawings, and claims.

FIG. 1 is a schematic drawing of a sense amplifier in accordance with a first embodiment of the invention.

FIG. 2 is a schematic drawing of a sense amplifier in accordance with a second embodiment.

FIG. 3 is a schematic drawing of a sense amplifier in accordance with a third embodiment.

FIG. 4 is a chart of waveforms illustrating performance of the sense amplifier depicted in FIG. 1 operating in conjunction with reading a memory cell.

FIG. 5 is a flowchart of a method according to an embodiment of the invention.

Like reference symbols in the various drawings indicate like elements.

### DETAILED DESCRIPTION

Embodiments or examples illustrated in the drawings are now being described using specific language. It will nevertheless be understood that the embodiments and examples are not intended to be limiting. Any alterations and modifications in the described embodiments, and any further applications of principles of the invention described in this document are contemplated as would normally occur to one skilled in the pertinent art. Reference numbers may be repeated throughout the embodiments, but this does not necessarily require that feature(s) of one embodiment apply to another embodiment, even if they share the same reference number.

### Illustrative Circuit Embodiments

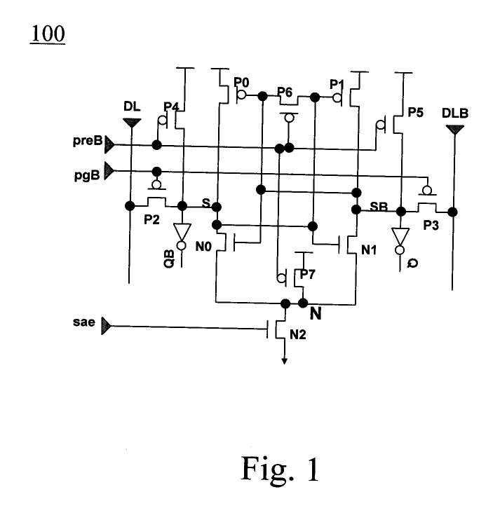

FIG. 1 shows a sense amplifier (SA) 100, in accordance with an embodiment. Signal preB controls transistors P4, P5, and P6 to pre-charge and equalize nodes S and SB. When signal preB is activated (e.g., driven low), transistors P4 and P5 are turned on and supply operating voltage Vdd from transistors P4 and P5 to be transferred to nodes S and SB or to (pre-)charge nodes S and SB. The term pre-charge is commonly used to refer to charging the nodes before reading the data. The activated signal preB also turns on transistor P6 making it a virtual short, and thus enabling the voltage at its drain and source or at nodes S and SB to be equal. Transistors P4, P5, and P6 together with signal preB may be referred to as a pre-charge and equalizing circuit because they pre-charge and equalize data (e.g., the voltage level) at nodes S and SB. Because nodes S and SB are coupled to the gate of transistors P1 and P0, when nodes S and SB are charged (e.g., driven high), they turn off transistors P1 and P0, respectively.

Transistors P0, P1, N0, and N1 form a cross latch for SA 100, e.g., cross latch CX (not labeled). Nodes S and SB are commonly referred to as the internal nodes of cross latch CX, and store data for cross latch CX or for SA 100 from which this data can be read out through node QB and/or Q. In various embodiments, if node S is pulled lower than node SB, the read out data at node Q is low. In contrast, if node S is higher than node SB, the read out data at node Q is high.

Lines DL and DLB serve to receive input data (e.g., from a memory cell). The data on these two lines DL and DLB when appropriate is passed (e.g., preset) to nodes S and SB via transistor P2 and P3, respectively. When SA 100 is used with a memory, e.g., in a read operation, the data in a bit cell being read discharges the data on line DL or DLB, making the level of one line lower than the level of the other line.

Signal pgB controls transistors P2 and P3. When signal pgB is activated (e.g., driven low), data on lines DL and DLB are transferred to nodes S and SB. Transistors P2 and P3 are configured to have their drains connected to the drains of transistors N1 and NO (or the source of transistors P1 and P0), and as a result enable the transfer of data on lines DLB and DL to nodes SB and S, respectively.

Signal sae controls transistor N2 and thus cross latch CX. When signal sae is activated (e.g., driven high), it turns on transistor N2, and as a result provides a current path for cross latch CX so that cross latch CX can be on and function.

Signal preB also controls transistor P7. When signal preB is activated, in addition to turning on transistors P4, P5, and P6, it turns on transistor P7, and when it is deactivated, it turns off transistor P7. Transistor P7, when activated, provides a known voltage level at node N, which is the drain of transistor N2 and the source of transistors N0 and N1. For example, when nodes S and SB are charged to a high (e.g., Vdd), transistor P7 being on provides a high (e.g., also Vdd) to node N which enables both the gate and the source of transistors N0 and N1 to be equal to Vdd. As a result, voltage VGS (the voltage from the gate to the source) of these transistors N0 and N1 are at 0V, which mitigates the PBTI effect and thus stabilizes transistors N0 and N1, cross latch CX, and SA 100.

In various embodiments of the invention, nodes S and SB are high in many situations, e.g., when the cross latch CX is off, before transferring data on lines DL and DLB to nodes S and SB, before activating signal sae to turn on cross latch CX to read the data, etc. Providing the high voltage level at node N in those situations is beneficial, and is advantageous over other approaches because the unknown state otherwise at node N at that time can degrade performance of sense amplifier 100. For example, without transistor P7, the voltage level at node N or at the source of transistors N0 and N1 is unknown, which could be less than Vdd. Because the gates of transistors N0 and N1 (e.g., nodes S and SB) are at Vdd, and their sources are less than Vdd, voltage VGS of transistors N0 and N1 are at some voltage levels (e.g., voltage Vdd minus the unknown voltage level), instead of being at 0V for them to be completely off, causing these transistors N0 and N1 to be subject to the PBTI effect or stress. In various embodiments, cross latch CX is on for sensing data for a short period, and therefore cross latch CX is off most of the time, and the long unknown state at node N can cause transistors N0 and N1 to suffer from the PBTI effect for a long time.

In ideal situations, transistors N0 and N1 are compatible (e.g., are of the same type, same size, same driving capabilities, same threshold voltage, etc.) so that sensing data by SA 100 depends mainly on data on lines DL and DLB but do not depend on the strong pull of one transistor N0 or N1. In reality there are mismatches between these transistors (e.g., one transistor is stronger with a better driving capability than the other transistor), which can worsen the PBTI effect. Embodiments as illustrated above reduce the PBTI effect, including the PBTI effect worsened by the mismatch between transistors N0 and N1.

PMOS transistor P7 shown in FIG. 1 is merely for illustration, but embodiments are not so limited. Any other mechanisms including devices, circuits, combinations thereof that can enable node N to be at a known voltage level are within scope of the disclosure. Further, signal preB used to control transistor P7 is also shown for illustration in which transistors P4, P5, and P6, and P7 may be activated at the same time. Another signal different from signal preB and/or independent of transistors P4, P5, and P6 may be used to control (e.g., activate/deactivate) transistor P7 as appropriate.

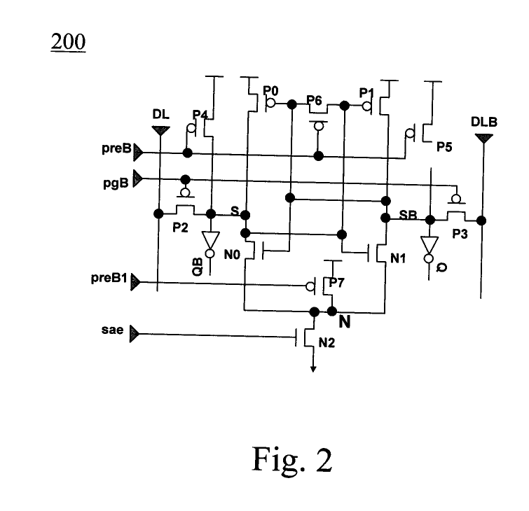

FIG. 2 shows a SA 200 in accordance with a second embodiment in which a transistor P7 is controlled by an independent signal, e.g., signal preB1. Compared with SA 100 (FIG. 1), signal preB1 is independent from (e.g., not coupled to) signal preB, and thus the on/off status of transistor P7 is independent from transistors P4, P5, P6 controlled by signal preB. Consequently, depending on a given application, signal preB1 may turn on transistor P7 and charge node N to a known state independent of nodes S and SB being charged by signal preB and transistors P4, P5, and P6.

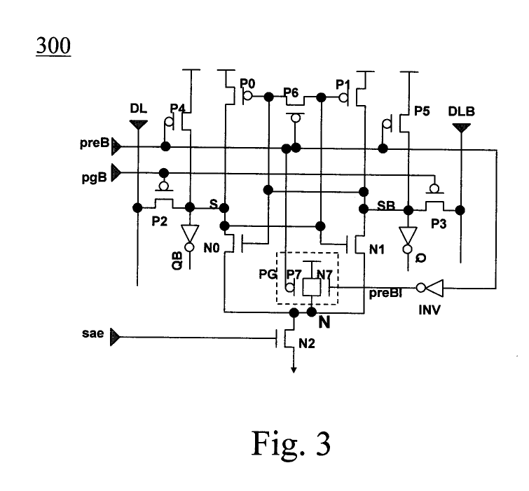

FIG. 3 shows a SA 300 in accordance with a third embodiment. Compared with SA 100 (FIG. 1), SA 300 includes pass gate PG comprising transistors P7 and N7, and inverter INV that function in place of transistor P7 in SA 100. Inverter INV inverts signal preB to provide a signal (e.g., signal preBI), which, together with signal preB controls pass gate PG. Similar to transistor P7, pass gate PG provides a known state (e.g., Vdd) to node N as appropriate, consistent with the spirit and scope of embodiments described herein. Similar to transistor P7 in SA 200 having an independent control signal preB1, pass gate PG may have control signals, e.g., signals preBPG and preBPGI inverted from signal preBPG (not shown), independent of signal preB. Consequently, pass gate PG may provide a known state to node N independent of nodes S and SB being charged by signal preB, transistors P4, P5, and P6.

### Illustrative Waveforms

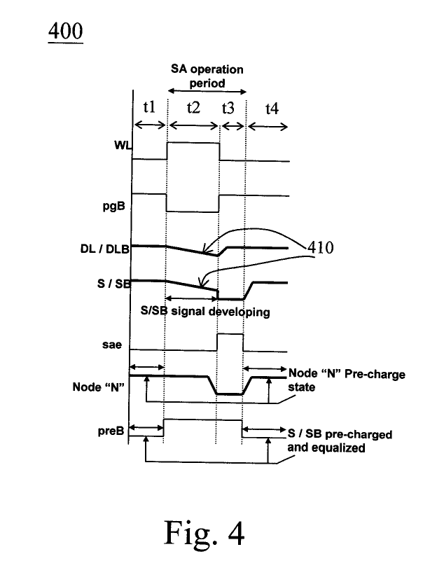

FIG. 4 shows waveforms 400 illustrating operation of SA 100 in conjunction with reading a memory cell, in accordance with an embodiment.

During time period t1 (also known as a pre-charge period), SA 100, for example, is in an idle state, and the word line WL being low allows selection of a memory cell to be read. Signal sae being low turns off cross latch CX (e.g., through time t2). Signal preB being low turns on transistors P4, P5, and P6, and pre-charges and equalizes nodes S and SB to a high.

Signal preB being low also turns on transistor P7 and provides a high voltage level to node N. Because nodes S and SB are high, each gate of transistors N0 and N1 is high. Because node N is high, each source of transistors N0 and N1 is high. As a result, voltage VGS of transistors N0 and N1 is 0V, mitigating the PBTI effects on transistors N0 and N1, stabilizing SA 100. Node N continues to be high through time periods t1 and t2.

Signal pgB being high turns off transistor P2 and P3 preventing data on lines DL and DLB from being transferred to nodes S and SB. By this time, an independent circuit (not show) has charged lines DL and DLB to a high.

During time period t2 (also known as a charging period), word line WL being high selects the memory cell to be read. The data in the memory cell is transferred to lines DL and DLB. Signal pgB being low turns on transistors P2 and P3, allowing data on lines DL and DLB to be transferred to nodes S and SB. The data in the memory cell pulls one data line DL or DLB and thus node S or node SB low while allowing the other data line to remain high. The slope of line 410 illustrates this effect.

Signal preB is pulled high ending the charging period.

During time period t3, signal sae is activated high and turns on transistor N2 and thus cross latch CX. During time period t3, signal at nodes S and SB are fully developed from a differential signal to a full rail-to-rail signal.

Word line WL is deactivated allowing SA 100 to be in the idle state. Signal pgB is high to turn off transistors P2 and P3 so that signals at nodes S and SB are independent of data lines DL and DLB.

SA 100 may be considered in operation during time t2 and t3.

During time period t4, signal sae is deactivated low turning off cross latch CX. Signal preB is activated low to charge nodes S and SB, and node N. As a result, voltage VGS of each of transistors N0 and N1 is 0V, mitigating the PBTI effects on transistors N0 and N1, stabilizing SA 100.

In the above illustration, during time periods t1, t2, and t4, when cross latch CX are off, node N is charged to a known state (such as a high voltage level in the embodiments), which is advantageous over other approaches where node N is in an unknown state, subjecting transistors N0 and N1 to the PBTI effect.

### Illustrative Method Embodiment

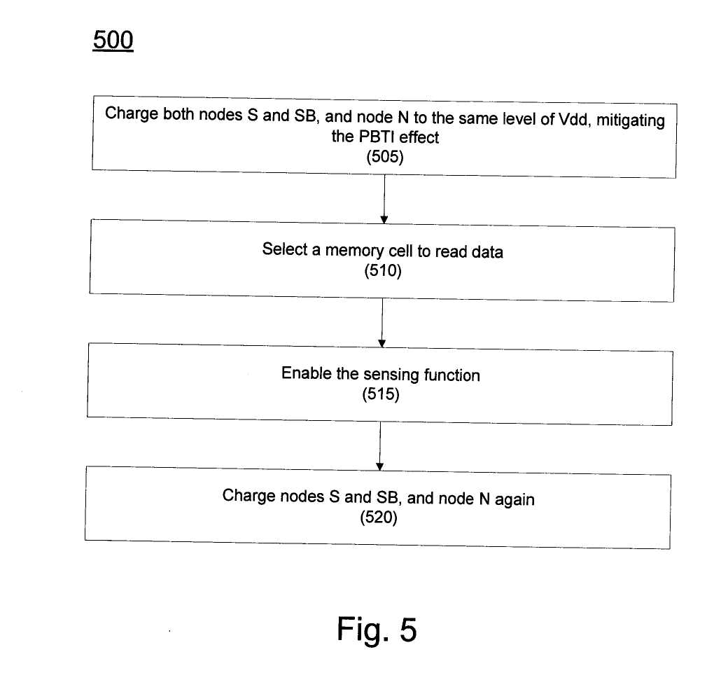

FIG. 5 shows a flowchart illustrating a method embodiment in which SA 100 operates in conjunction with reading a memory cell.

At step 505, signal preB is activated by being pulled to a low voltage level to turn on transistors P4, P5, P6, and P7, wherein transistors P4, P5, and P6 charge nodes S and SB, and transistor P7 charges node N, to operating voltage Vdd of transistors P4 and P5 and of transistor P7. In this illustration, nodes S and SB and N are concurrently charged, e.g., brought to the level of voltage Vdd. As a result, voltage VGS of both transistors N0 and N1 is 0V, mitigating the PBTI effect.

At step 510, word line WL is activated by being pulled to a high voltage level to select a memory cell to be read. The data in the memory cell is reflected on data lines DL and DLB. At the same time, signal pgB is activated by being pulled to a low voltage level to turn on transistors P2 and P3 that allow data on lines DL and DLB to be transferred to nodes S and SB. The data in the memory cell pulls the voltage level at one node S or SB low and allows the level on the other node to remain the same.

At step 515, signal sae is activated by being pulled to a high voltage level to turn on transistor N2 and thus cross latch CX, enabling the sensing function of SA 100, which allows the signal from nodes S and SB to fully develop and ready to be read out.

At step 520, signal sae is deactivated by being pulled to a low voltage level and signal preB is activated by being pulled to a low voltage level which enables nodes S and SB, and node N to be charged again.

In the above illustration, node N is charged in both steps 505 and 520. Without mechanisms as disclosed by exemplary embodiments, it would otherwise causes transistors N0 and N1 to be more vulnerable to the PBTI effect.

A number of embodiments have been described. It will nevertheless be understood that various modifications may be made without departing from the spirit and scope of the invention. For example, the various transistors being shown as a particular dopant type (e.g., NMOS and PMOS) are for illustration purposes, embodiments of the disclosure are not limited to a particular type, but the dopant type selected for a particular transistor is a design choice and is within the scope of embodiments. The logic level (e.g., low or high) of the various signals used in the above description is also for illustration purposes, embodiments are not limited to a particular level when a signal is activated and/or deactivated, but, rather, selecting such a level is a matter of design choice.

The above method embodiments show exemplary steps, but they are not necessarily required to be performed in the order shown. Steps may be added, replaced, changed order, and/or eliminated as appropriate, in accordance with the spirit and scope of disclosed embodiments.

Each claim of this document constitutes a separate embodiment, and embodiments that combine different claims and/or different embodiments are within scope of the disclosure and will be apparent to those skilled in the art after reviewing this disclosure. Accordingly, the scope of the invention should be determined with reference to the following claims, along with the full scope of equivalences to which such claims are entitled.

What is claimed is:

1. A circuit comprising:
a cross latch including
a pair of nodes including a first node and a second node, configured to store data for the cross latch;
a first pair of transistors;
a second pair of NMOS transistors including a first NMOS transistor and a second NMOS transistor; a first gate of the first NMOS transistor being coupled to the first node; a second gate of the second NMOS transistor being coupled to the second node;
a third node coupling a first source of the first NMOS transistor and a second source of the second NMOS transistor; and
circuitry configured to provide a voltage level to the third node.

2. The circuit of claim 1 wherein the circuitry includes a control signal affecting providing the voltage level to the third node.

3. The circuit of claim 2 wherein the control signal is coupled to a signal used to charge the pair of nodes.

4. The circuit of claim 1 wherein the circuitry includes a transistor or a pass gate configured to selectively provide the voltage level to the third node.

5. The circuit of claim 1 wherein the voltage level to the third node is such that VGS of the first NMOS transistor and of the second NMOS transistor is 0V.

6. The circuit of claim 1 wherein the voltage level is the same as a voltage level of the pair of nodes after the pair of nodes being charged.

7. The circuit of claim 1 further comprising a third NMOS transistor connected to the first and the second sources of the first and the second NMOS transistors, and the circuitry is configured to provide the voltage level to the third node when the third NMOS transistor is off.

8. The circuit of claim 1 wherein the cross latch is used in a sense amplifier.

9. A circuit comprising:
a cross latch including
a pair of nodes including a first node and a second node, configured to store data for the cross latch;
a pair of transistors including a first transistor and a second transistor; a first gate of the first transistor being coupled to the first node; a second gate of the second transistor being coupled to the second node;
a third node coupling a first terminal of the first transistor and a second terminal of the second transistor;
a third transistor coupled to the third node and configured to provide a current path for the cross latch;
first circuitry configured to provide a first voltage level to the pair of nodes;
second circuitry configured to provide a second voltage level to the third node.

10. The circuit of claim 9, wherein the first transistor, the second transistor, and the third transistor are NMOS.

11. The circuit of claim 9 further comprising a control signal concurrently affecting both providing the first voltage level to the pair of nodes and providing the second voltage level to the third node.

12. The circuit of claim 9, wherein the first voltage level and the second voltage level are equal to an operating voltage of transistors in the circuit.

13. The circuit of claim 9, wherein the second circuitry includes a transistor or a pass gate.

14. The circuit of claim 9, wherein the second circuitry provides the second voltage level to the third node when the third transistor is off.

15. A sense amplifier comprising:
a cross latch including
a pair of nodes including a first node and a second node, configured to store data for the sense amplifier;
a pair of transistors including a first transistor and a second transistor; a first gate of the first transistor being coupled to the first node; a second gate of the second transistor being coupled to the second node;
a third node coupling a first source of the first transistor and a second source of the second transistor;
first circuitry configured to provide a first voltage level to the pair of nodes;
second circuitry configured to provide a second voltage level to the third node.

16. The sense amplifier of claim 15, wherein the first transistor and the second transistor are NMOS.

17. The sense amplifier of claim 15, wherein the first voltage level and the second voltage level are the same.

18. The sense amplifier of claim 15 further comprising a control signal concurrently affecting both providing the first voltage level to the pair of nodes and providing the second voltage level to the third node.

19. The sense amplifier of claim 15, wherein the second circuitry includes a PMOS transistor or a pass gate.

20. The sense amplifier of claim 15 further comprising a third transistor coupled to the third node, and the second circuitry is configured to provide the second voltage level to the third node when the third transistor is off.
